(19) United States
(12) Patent Application Publication
(10) Pub. No.: US 2025/0140700 A1
(43) Pub. Date: May 1, 2025

(54) SUBSTRATE INCLUDING CONDUCTIVE STUD ON PAD STRUCTURE

(71) Applicant: QUALCOMM Incorporated, San Diego, CA (US)

(72) Inventors: Joan Rey Villarba BUOT, Escondido, CA (US); Hong Bok WE, San Diego, CA (US); Michelle Yejin KIM, Carlsbad, CA (US); Aniket PATIL, San Diego, CA (US); Yu-Ting HUANG, Taoyuan Dist, Taoyuan City (TW)

(21) Appl. No.: 18/494,115

(22) Filed: Oct. 25, 2023

(51) Int. Cl. H01L 23/538; H01L 21/48; H01L 25/10

(52) U.S. Cl. CPC H01L 23/5383; H01L 21/4857; H01L 21/486; H01L 23/5384; H01L 23/5386; H01L 25/105

(57) ABSTRACT

In an aspect, a substrate for an integrated circuit (IC) package includes a first dielectric layer, a first metallization layer on a first surface of the first dielectric layer and including a first pad structure and a first trace structure, a second metallization layer on a second surface of the first dielectric layer and including a second pad structure and a second trace structure, a second dielectric layer on the second surface of the first dielectric layer, and a third metallization layer on a second surface of the second dielectric layer and having a third pad structure. The substrate further includes a conductive stud coupled to the second pad structure and a second via structure embedded in the second dielectric layer. The second via structure has a first end coupled to the conductive stud and a second end coupled to the third pad structure.

### TECHNICAL FIELD

The present disclosure generally relates to a substrate for an integrated circuit (IC) package, and more particularly, to a substrate including a conductive stud on a pad structure.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

For example, a package on a package (POP) packaging method may correspond to vertically combining discrete logic and/or memory chips or dies to reduce the IC device size. In some examples, the POP packaging method may be used in conjunction with a molded embedded package packaging method, which may be referred to as a molded embedded package on a package packaging method or a MEP packaging method. In some examples, in an IC package formed based on the POP packaging method and/or the MEP packaging method, each chip may be mounted on a respective substrate, and a special type of substrate (also known as an interposer) may be used for coupling different substrates with chips mounted thereon.

In some examples, increasing the number of metallization layers of a substrate for an IC package may increase the routing flexibility of the IC package and thus may enhance the functionality and/or performance of the resulting IC device. In some examples, increasing the number of metallization layers of a substrate for an IC package may also increase the overall thickness of the IC package, which may affect the overall size of the electronic device incorporating the resulting IC device and thus may have a negative impact to the overall product design constraints and/or the market competitivity of the electronic device.

Accordingly, there is a need for improved substrates for an IC package and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a substrate for an integrated circuit (IC) package includes a first dielectric layer; a first metallization layer on a first surface of the first dielectric layer, the first metallization layer including a first pad structure and a first trace structure; a second metallization layer on a second surface of the first dielectric layer, the second metallization layer including a second pad structure and a second trace structure; a conductive stud coupled to the second pad structure; a second dielectric layer on the second surface of the first dielectric layer, a first surface of the second dielectric layer facing the second surface of the first dielectric layer, and the second metallization layer and the conductive stud being at least partially embedded in the second dielectric layer; a second via structure embedded in the second dielectric layer, the second via structure having a first end coupled to the conductive stud; and a third metallization layer on a second surface of the second dielectric layer and having a third pad structure, the second via structure having a second end coupled to the third pad structure.

In an aspect, a method of manufacturing a substrate for an integrated circuit (IC) package includes forming a first metallization layer on a first surface of a first dielectric layer, the first metallization layer including a first pad structure and a first trace structure; forming a second metallization layer on a second surface of the first dielectric layer, the second metallization layer including a second pad structure and a second trace structure; forming a conductive stud coupled to the second pad structure; forming a second dielectric layer on the second surface of the first dielectric layer, a first surface of the second dielectric layer facing the second surface of the first dielectric layer, and the second metallization layer and the conductive stud being at least partially embedded in the second dielectric layer; forming a second via structure embedded in the second dielectric layer, the second via structure having a first end coupled to the conductive stud; and forming a third metallization layer on a second surface of the second dielectric layer and having a third pad structure, the second via structure having a second end coupled to the third pad structure.

In an aspect, an electronic device includes an integrated circuit (IC) package including: a first dielectric layer; a first metallization layer on a first surface of the first dielectric layer, the first metallization layer including a first pad structure and a first trace structure; a second metallization layer on a second surface of the first dielectric layer, the second metallization layer including a second pad structure and a second trace structure; a conductive stud coupled to the second pad structure; a second dielectric layer on the second surface of the first dielectric layer, a first surface of the second dielectric layer facing the second surface of the first dielectric layer, and the second metallization layer and the conductive stud being at least partially embedded in the second dielectric layer; a second via structure embedded in the second dielectric layer, the second via structure having a first end coupled to the conductive stud; and a third metallization layer on a second surface of the second dielectric layer and having a third pad structure, the second via structure having a second end coupled to the third pad structure.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a cross-sectional view of an integrated circuit (IC) package, according to aspects of the disclosure.

FIG. 2A illustrates a portion of a first substrate example for an IC package, according to aspects of the disclosure.

FIG. 2B illustrates a portion of a second substrate example for an IC package, according to aspects of the disclosure.

FIGS. 3A-3J illustrate structures at various stages of manufacturing a substrate for an IC package, according to aspects of the disclosure.

FIG. 4 illustrates a method for manufacturing a substrate for an IC package, according to aspects of the disclosure.

FIG. 5 illustrates a mobile device, according to aspects of the disclosure.

FIG. 6 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a.” “an,” and “the” are intended to include the plural forms as well, unless the context clearly indicates otherwise. It will be further understood that the terms “comprises,” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to manufacturing a substrate that includes a metallization layer having a reduced thickness and a conductive stud coupled to a pad structure of the metallization layer to increase the overall margin for the drilling the openings for forming stacked via structures. In some aspects, the substrate may correspond to a package substrate (e.g., an interposer) in an IC package.

Particular aspects of the subject matter described in this disclosure can be implemented to realize one or more of the following potential advantages. In some examples, the risk of having the drilling processes punching through the openings for the stacked via structures may be reduced without increasing the thickness of the metallization layer. Also, the overall thickness of the IC package incorporating such substrate may be reduced.

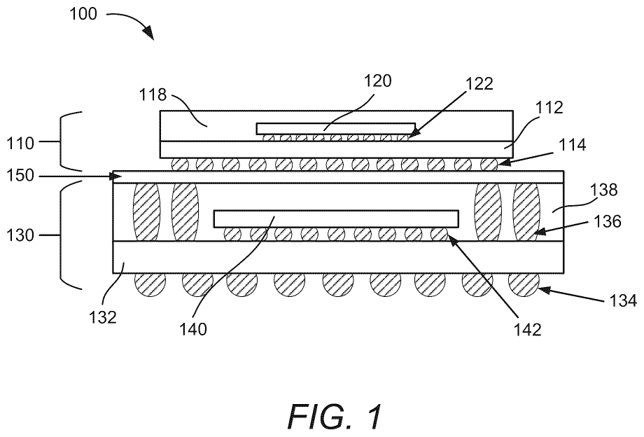

FIG. 1 is a cross-sectional view of an IC package 100, according to aspects of the disclosure. In some aspects, FIG. 1 is a simplified cross-sectional view of the IC package 100, and certain details and components of the IC package 100 may be simplified or omitted in FIG. 1.

In some aspects, as shown in FIG. 1, the IC package 100 may be based on the POP packaging method. The IC package 100 may include a first packaging portion 110 over a second packaging portion 130, with an interposer 150 coupling the first packaging portion 110 to the second packaging portion 130.

The first packaging portion 110 may include a first substrate 112 and first packaging terminals 114 (e.g., solder bumps or copper pillar bumps) electrically coupling the first substrate 112 and the interposer 150. In some aspects, the first packaging terminals 114 may also be configured to mechanically coupling the first substrate 112 and the interposer 150. The first packaging portion 110 may include a first IC chip 120 mounted on the first substrate 112 through first IC terminals 122 (e.g., solder bumps or copper pillar bumps). In some aspects, the first packaging portion 110 may further include a first molding compound portion 118 disposed on the first substrate 112 and covering the first IC chip 120. In some aspects, the first molding compound portion 118 may only surround the first IC terminals 122 without covering the first IC chip 120. In some aspects, the first packaging portion 110 may not include the first molding compound portion 118. In some aspects, the first IC terminals 122, the first molding compound portion 118, or both may also be configured to mechanically coupling the first IC chip 120 and the first substrate 112.

The second packaging portion 130 may include a second substrate 132 and second packaging terminals 134 (e.g., solder bumps or copper pillar bumps) for electrically coupling the IC package 100 to an external component, such as a circuit board. The second packaging portion 130 may include a second IC chip 140 mounted on the second substrate 132 through second IC terminals 142 (e.g., solder bumps or copper pillar bumps). The second packaging portion 130 may include conductive structures 136 (e.g., solder bumps, copper pillar bumps, or through vias) electrically coupling the second substrate 132 and the interposer 150. In some aspects, the second packaging portion 130 may further include a second molding compound portion 138 disposed on the second substrate 132 and covering the second IC chip 140. In some aspects, the second molding compound portion 138 may surround the conductive structures 136. In some aspects, the second molding compound portion 138 may only surround the second IC terminals 142 without covering the second IC chip 140 and/or without surrounding the conductive structures 136. In some aspects, the second packaging portion 130 may not include the second molding compound portion 138.

In some aspects, the second IC terminals 142, the second molding compound portion 138, or both may also be configured to mechanically coupling the second IC chip 140 and the second substrate 132. In some aspects, the conductive structures 136, the second molding compound portion 138, or both may also be configured to mechanically coupling the second substrate 132 and the interposer 150.

As used herein, the interposer 150 is configured to electrically couple the substrates 112 and 132 and in some aspects coupling the IC chips 120 and 140 through the substrates 112 and 132 and optionally additional components (e.g., other IC chips, active components such as discrete transistors or Op Amps, and/or passive components such as resistors, capacitors, and/or inductors) formed on or embedded in the substrate 112 and/or the substrate 132.

It will be appreciated that the illustrated configuration and descriptions provided herein are merely to aid in the explanation of the various aspects disclosed herein. Accordingly, the forgoing illustrative examples should not be construed to limit the various aspects disclosed and claimed herein.

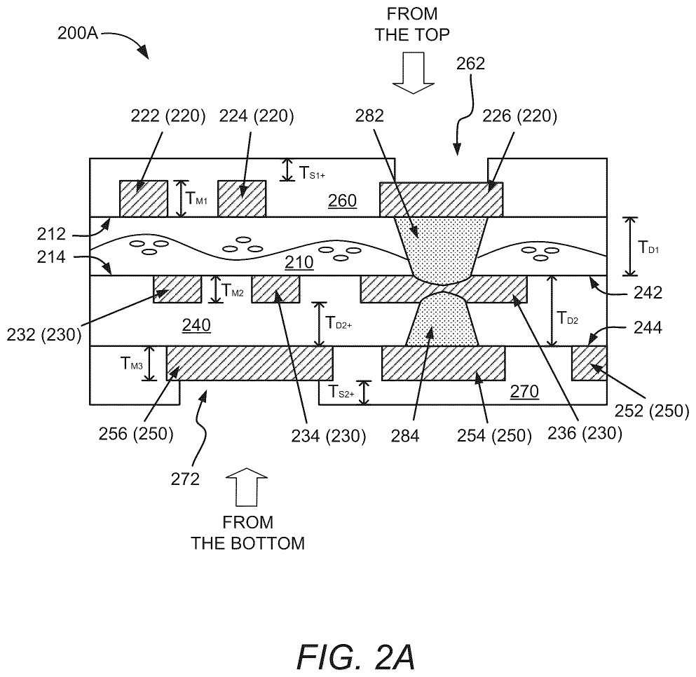

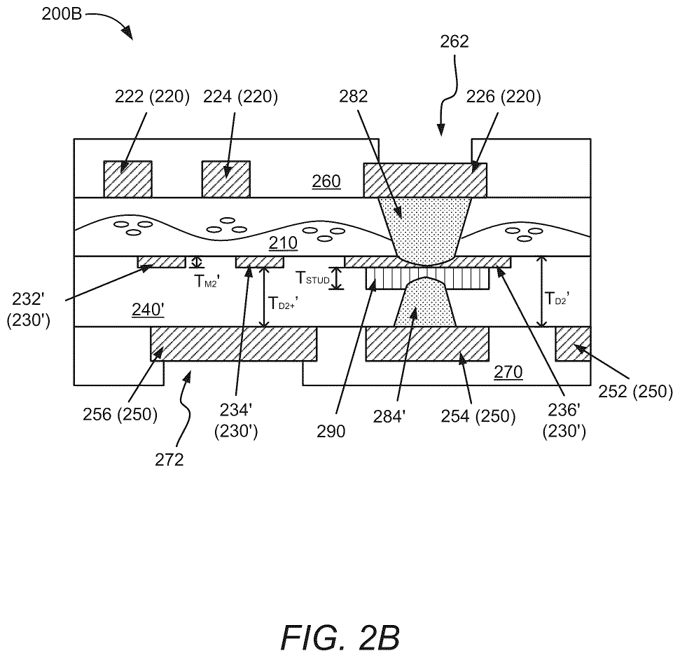

FIG. 2A illustrates a portion of a first substrate example 200A for an IC package, according to aspects of the disclosure. In some aspects, the first substrate example 200A may correspond to the first substrate 112, the second substrate 132, or the interposer 150 in FIG. 1.

As shown in FIG. 2A, the first substrate example 200A may include a first dielectric layer 210, a first metallization layer 220 on a first surface 212 of the first dielectric layer 210, a second metallization layer 230 on a second surface 214 of the first dielectric layer 210. The first dielectric layer 210 may include a dielectric material with pre-impregnated reinforcement components embedded therein. In some aspects, the first dielectric layer 210 may include prepregs (also known as PPG), which may include polymer resins with fiber glass sheets impregnated therein. In some aspects, a thickness T_{D1} of the first dielectric layer 210 may range from 15 to 30 micrometers (μm). In some aspects, the thickness T_{D1} may be about 20 μm.

The first metallization layer 220 may include one or more trace structures 222 and 224 and one or more pad structures 226. In some aspects, a thickness T_{M1} of the one or more trace structures 222 and 224 and/or the one or more pad structures 226 may range from 10 μm to 15 μm. In some aspects, the thickness T_{M1} may be about 13 μm. In some aspects, the first metallization layer 220 may include a conductive material such as copper. The second metallization layer 230 may include one or more trace structures 232 and 234 and one or more pad structures 236. In some aspects, a thickness T_{M2} of the one or more trace structures 232 and 234 and/or the one or more pad structures 236 may range from 8 μm to 15 μm. In some aspects, the thickness T_{M2} may be about 10 μm. In some aspects, the second metallization layer 230 may include a conductive material such as copper.

As shown in FIG. 2A, the first substrate example 200A may include a second dielectric layer 240 on the second surface 214 of the first dielectric layer 210. In some aspects, a first surface 242 of the second dielectric layer 240 may face the second surface 214 of the first dielectric layer 210. In some aspects, the second metallization layer 230 may be at least partially embedded in the second dielectric layer 240. In some aspects, a thickness T_{D2+} measuring a portion of the thickness of the second dielectric layer beyond the second metallization layer 230 may range from 18 μm to 30 μm. In some aspects, the thickness T_{D2+} may be about 22 μm. In some aspects, the overall thickness T_{D2} of the second dielectric layer 240 may range from 26 μm to 45 μm.

As shown in FIG. 2A, the first substrate example 200A may include a third metallization layer 250 on a second surface 244 of the second dielectric layer 240. The third metallization layer 250 may include one or more trace structures 252 and one or more pad structures 254 and 256. In some aspects, a thickness T_{M}_{₃} of the one or more trace structures 252 and/or the one or more pad structures 254 and 256 may range from 10 μm to 15 μm. In some aspects, the thickness T_{M3} may be about 13 μm. In some aspects, the third metallization layer 250 may include a conductive material such as copper.

Moreover, the first substrate example 200A may include a first solder resist layer 260 covering at least a portion of the first surface 212 of the first dielectric layer 210 and a portion of the first metallization layer 220. For example, the first solder resist layer 260 may have an opening 262 defined therein that exposes a portion of the pad structure 226. In some aspects, a thickness T_{S1+} measuring a portion of the thickness of the first solder resist layer 260 beyond the first metallization layer 220 may range from 10 μm to 15 μm. In some aspects, the thickness T_{S1+} may be about 12 μm.

Also, the first substrate example 200A may include a second solder resist layer 270 covering at least a portion of the second surface 244 of the second dielectric layer 240 and a portion of the third metallization layer 250. For example, the second solder resist layer 270 may have an opening 272 defined therein that exposes a portion of the pad structure 256. In some aspects, a thickness T_{S2+} measuring a portion of the thickness of the second solder resist layer 270 beyond the third metallization layer 250 may range from 10 μm to 15 μm. In some aspects, the thickness T_{S2+} may be about 12 μm.

As shown in FIG. 2A, the first substrate example 200A may include a first via structure 282 embedded in the first dielectric layer 210 and a second via structure 284 embedded in the second dielectric layer 240. In some aspects, the first via structure 282 may include a first end coupled to the pad structure 236 and a second coupled to the pad structure 226. In some aspects, the second via structure 284 may include a first end coupled to the pad structure 236 and a second coupled to the pad structure 254. In some aspects, one or more bump structures (not shown in FIG. 2A) may be formed in the openings 262 and 272 and electrically coupled to the pad structures 226 and 256.

In some aspects, the first via structure 282 and the second via structure 284 may include a conductive material such as copper. In some aspects, the first via structure 282 may be formed based on an opening through the first dielectric layer 210, and such opening may be defined by performing a mechanical drilling process or a laser drilling process (e.g., by using a CO₂ laser) from the top of the first substrate example 200A (indicated by the arrow with the label “FROM THE TOP”). Also, the second via structure 284 may be formed based on an opening through the second dielectric layer 240, and such opening may be defined by performing another mechanical drilling process or another laser drilling process (e.g., by using a CO₂ laser) from the bottom of the first substrate example 200A (indicated by the arrow with the label “FROM THE BOTTOM”).

In some aspects, in order to reduce the overall thickness of the IC package (e.g., the IC package 100), one approach may be reducing the thickness of the substrate (e.g., the substrate 112, the substrate 132, or the interposer 150). In the example shown in FIG. 2A, the thickness of the second metallization layer 230 (e.g., the thickness T_{M2}) may be reduced. However, having a thinner thickness may increase the risk of punching through the pad structure 236 during the laser drilling processes for defining the openings for the first via structure 282 and the second via structure 282. In some aspects, the openings may be filled with copper by a copper plating process, and the penetrated pad structure may cause voids or cracks in the first via structure 282 and/or the second via structure 282 during the copper plating process. This may cause degradation of the reliability of stacked vias (e.g., the first via structure 282 and the second via structure 284 stacked one over the other). To address the reliability issue, one approach may be increasing (or not reducing) the thickness of the second metallization layer 230, which may lead to a thicker substrate. Another approach may be avoiding having stacked vias, which may limit the routing flexibility of the substrate and thus cause performance degradation.

FIG. 2B illustrates a portion of a second substrate example 200B for an IC package, according to aspects of the disclosure. In some aspects, the second substrate example 200B may correspond to the first substrate 112, the second substrate 132, or the interposer 150 in FIG. 1. In some aspects, various components of the second substrate example 200B that are the same or similar to the components of the first substrate example 200A are given the same reference numbers, and detailed description thereof may be omitted.

As shown in FIG. 2B, the second substrate example 200B differs from the first substrate example 200A in that a thickness of the second metallization layer 230′ of the second substrate example 200B is less than the thickness of the second metallization layer 230 of the first substrate example 200A, and that a conductive stud 290 is disposed between a pad structure 236′ and a second via structure 284′.

As shown in FIG. 2B, the second substrate example 200B may include a first dielectric layer 210, a first metallization layer 220, and a third metallization layer 250 that are the same or similar to the counterpart components of the first substrate example 200A. The second metallization layer 230′ of the second substrate example 200B may have a thickness T_{M2}′ less than the thickness T_{M2} of the second metallization layer 230 of the first substrate example 200A. In some aspects, the second substrate example 200B may include a second dielectric layer 240′ that may differ from the second dielectric layer 240 in the second substrate example 200B by having a reduced overall thickness T_{D2}′ than the thickness T_{D2}. In some aspects, the second dielectric layer 240′ may be free from having glass fibers embedded therein. In some aspects, the second dielectric layer 240′ may be formed based on AJINOMOTO BUILD-UP FILM® (ABF), photo-imageable dielectrics (PID), and/or resin coated copper (RCC).

In some aspects, the second metallization layer 230′ of the second substrate example 200B may include one or more trace structures 232′ and 234′ and one or more pad structures 236′. In some aspects, a thickness T_{M2}′ of the one or more trace structures 232′ and 234′ and/or the one or more pad structures 236′ may be equal to or less than 6 μm. In some aspects, the thickness T_{M2}′ may range from 2 μm to 5 μm. In some aspects, the second metallization layer 230′ may include a conductive material such as copper. In some aspects, a thickness T_{D2+}′ measuring a portion of the thickness of the second dielectric layer 240′ beyond the second metallization layer 230′ may range from 18 μm to 30 μm or may be similar to the thickness T_{D2+} of the first substrate example 200A.

As shown in FIG. 2B, the second substrate example 200B may include the conductive stud 290 coupled to the pad structure 236′. In some aspects, the conductive stud 290 may include a conductive material such as copper. In some aspects, the second via structure 284′ of the second substrate example 200B may include a first end coupled to the conductive stud 290 and a second end coupled to the pad structure 254. In some aspects, a thickness T_{STUD} of the conductive stud 290 may range from 5 μm to 30 μm. Accordingly, a thickness of the one or more trace structures 232′ and 234′ (may be represented by the thickness T_{M2′}) may be less than a combined thickness of the pad structure 236′ and the conductive stud 290 (may be represented by the summation of thickness T_{M2′} and the thickness T_{STUD}).

In some aspects, compared with the first substrate example 200A, the conductive stud 290 of the second substrate example 200B may add effective thickness of conductive materials for the drilling process for the via structure 284′. Accordingly, the incorporation of the conductive stud 290 may mitigate the risk of drilling penetration without increasing (or with further reducing) the thickness of the second metallization layer 230′. As a result, the thickness of the second substrate example 200B as well as the overall thickness of the IC package incorporating the second substrate example 200B may be reduced. In some aspects, reducing the thickness of the second metallization layer 230′ may also reduce the risk of glass touch on the first dielectric layer 210. In some aspects, the glass touch issue may correspond to the glass fibers in a prepreg material or a core layer of the first dielectric layer 210 touching the metal layer (e.g., the second metallization layer 230′), which may lead to copper migration and thus may fail certain reliability requirements such as the reliability requirements set forth for a biased highly accelerated stress test (BHAST).

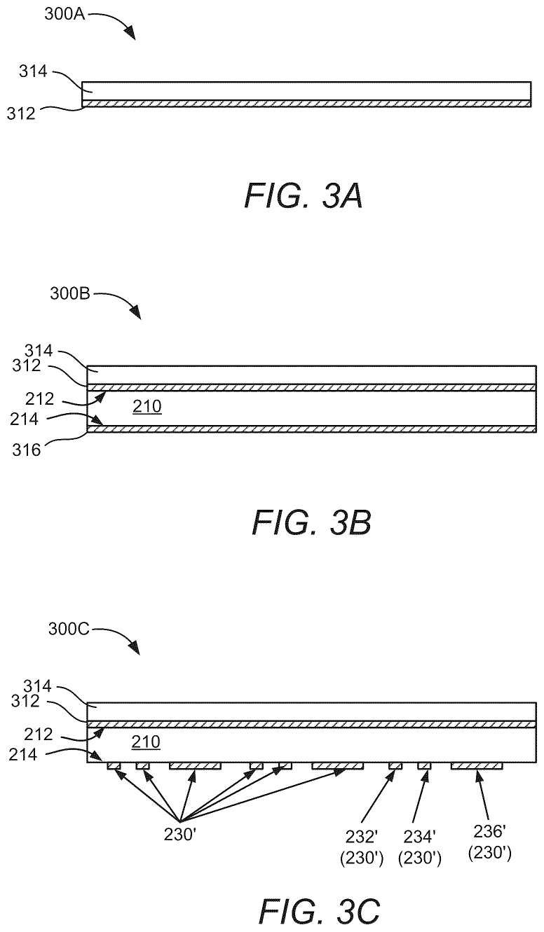

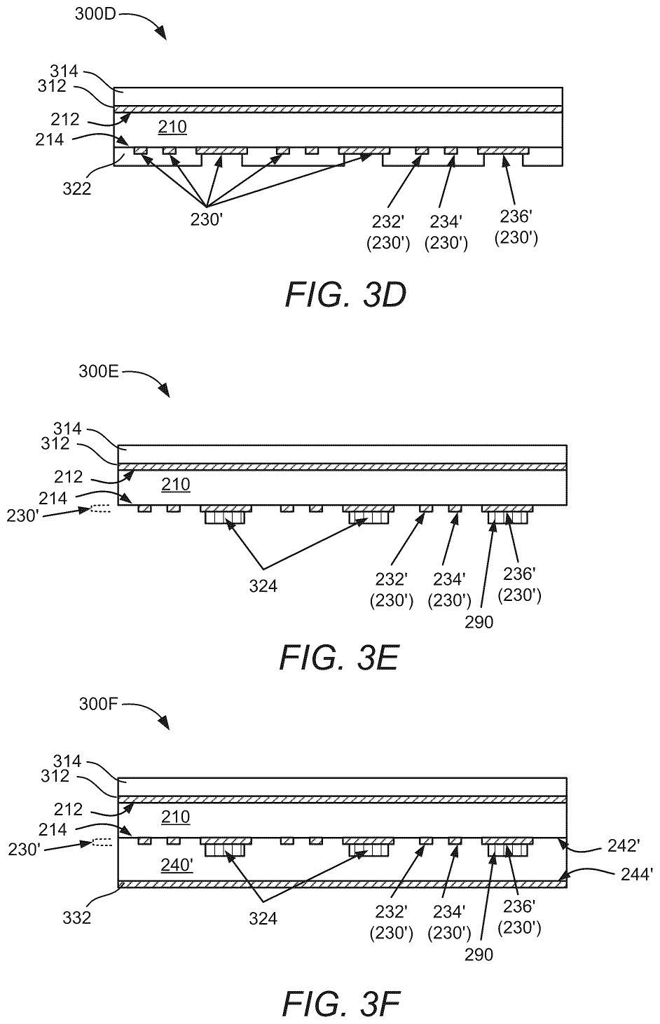

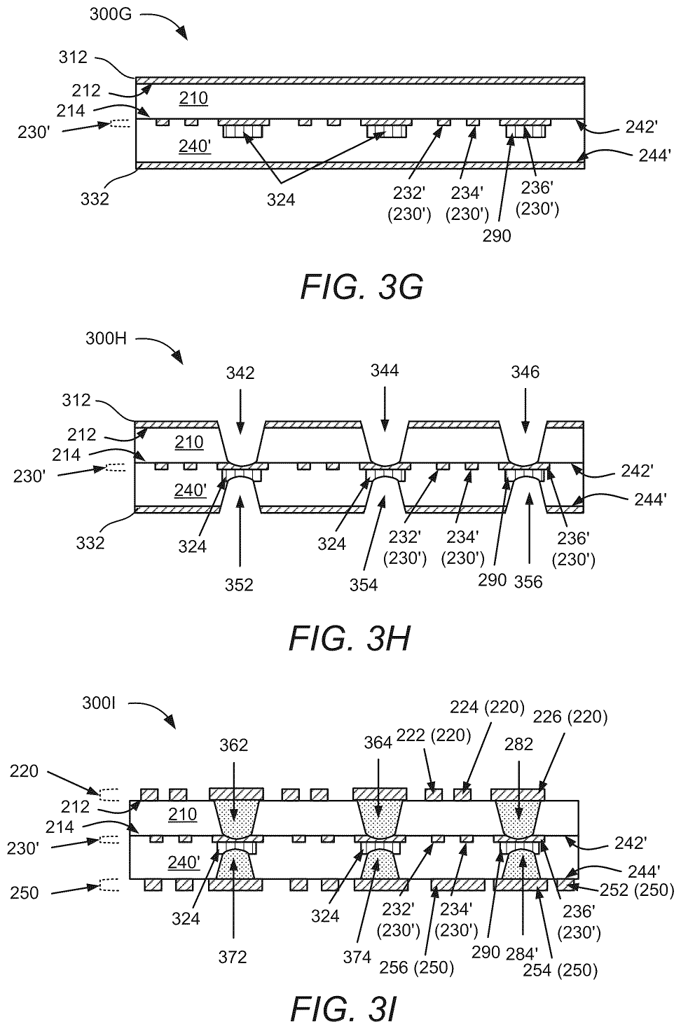

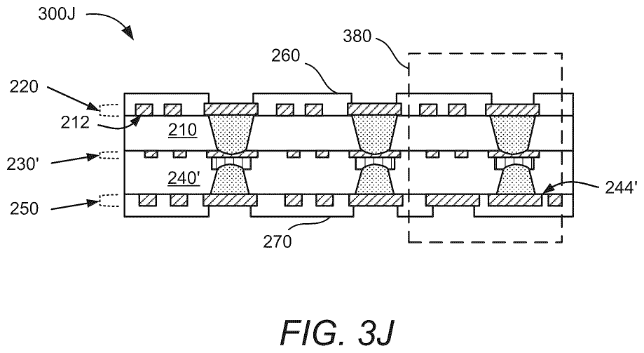

FIGS. 3A-3J illustrate structures at various stages of manufacturing a substrate for an IC package, such as the second substrate example 200B in FIG. 2B, according to aspects of the disclosure. The components illustrated in FIGS. 3A-3J that are the same or similar to those of FIG. 2B are given the same reference numbers, and the detailed description thereof may be omitted.

As shown in FIG. 3A, a structure 300A which includes a first conductive layer 312 and a carrier 314 disposed on the first conductive layer 312 is provided. In some aspects, the first conductive layer 312 may include a conductive material such as copper. In some aspects, the carrier 314 may include an insulation panel that can be chemically and/or mechanically removed from the first conductive layer 312 at a later stage. In some aspects, the structure 300A may be based on a detachable copper foil structure that is available as a pre-manufactured component.

As shown in FIG. 3B, a structure 300B is formed based on attaching a first dielectric layer 210 to the structure 300A (e.g., a detachable copper foil structure) and forming a second conductive layer 316 on a second surface 214 of the first dielectric layer 210. In some aspects, the first conductive layer 312 may be on a first surface 212 of the first dielectric layer 210. In some aspects, the first dielectric layer 210 may include a dielectric material with pre-impregnated reinforcement components embedded therein. In some aspects, the dielectric material may include resin, and the reinforcement components may include glass fibers. In some aspects, the resin may be in an uncured or not-fully-cured state at the stage of attaching the first dielectric layer 210 to the structure 300A and subsequently cured to complete the structure 300B. In some aspects, the second conductive layer 316 may include a conductive material such as copper.

In some aspects, the first dielectric layer 210 may be pre-manufactured with the second conductive layer 316 formed thereon before being attached to the structure 300A. In some aspects, the first dielectric layer 210 may be first laminated to the structure 300A, and then the second conductive layer 316 may be laminated to the first dielectric layer 210.

As shown in FIG. 3C, a structure 300C is formed based on the structure 300B by forming a second metallization layer 230′ on the second surface 214 of the first dielectric layer 210 based on the second conductive layer 316. In some aspects, the second metallization layer 230′ may include a pad structure 236′ and trace structures 232′ and 234′. In some aspects, the second metallization layer 230′ may be formed based on patterning the second conductive layer 316 to become conductive patterns, performing a plating process to increase the thickness of the conductive patterns, and optionally performing an etching and/or a cleaning process to remove excessive conductive materials on the second surface 214 of the first dielectric layer 210. In some aspects, the material and the thickness of the second metallization layer 230′ may be as discussed above with reference to FIG. 2B.

As shown in FIG. 3D, a structure 300D is formed based on the structure 300C by performing a masking process to form a layer of patterned masks 322 covering the trace structures of the second metallization layer 230′ (e.g., the trace structures 232′ and 234′) and exposing a portion of the pad structures of the second metallization layer 230′ (e.g., the pad structures 236′).

As shown in FIG. 3E, a structure 300E is formed based on the structure 300D by performing a plating process, using the layer of patterned masks 322 as masks, to form the conductive studs 324 and 290 on respective pad structures (e.g., the conductive stud 290 on the pad structure 236′). After the conductive studs 324 and 290 are formed, the layer of patterned masks 322 may be removed. In some aspects, the material and the thickness of the conductive stud 290 may be as discussed above with reference to FIG. 2B, which may be applicable to the conductive studs 324 as well.

As shown in FIG. 3F, a structure 300F is formed based on the structure 300E by forming a second dielectric layer 240′ on the second surface 214 of the first dielectric layer 210 and a third conductive layer 332 on the second dielectric layer 240′. In some aspects, a first surface 242′ of the second dielectric layer 240′ may be arranged to face the second surface 214 of the first dielectric layer 210. In some aspects, the second metallization layer 230′ and the conductive studs 324 and 290 may be at least partially embedded in the second dielectric layer 240′.

In some aspects, the second dielectric layer 240′ and the third conductive layer 332 may be based on an RCC layer that is available as a pre-manufactured component. In some aspects, the second dielectric layer 240′ and the third conductive layer 332 may be formed based on attaching the RCC layer to the first dielectric layer 210 after the second metallization layer 230′ and the conductive studs 324 and 290 are formed. In some aspects, the second dielectric layer 240′ may include resin in an uncured or not-fully-cured state at the stage attaching the RCC layer to the first dielectric layer 210 and may be subsequently cured to complete the structure 300F.

In some aspects, the second dielectric layer 240′ may be free from having glass fibers embedded therein. In some aspects, the second dielectric layer 240′ may be formed based on ABF, PID, and/or RCC.

As shown in FIG. 3G, a structure 300G is formed based on the structure 300F by removing the carrier 314 to expose the first conductive layer 312 after the conductive studs 324 and 290 are formed. In some aspects, the carrier 314 may be mechanically removed from the first conductive layer 312 (e.g., by machine slitting or peeling).

As shown in FIG. 3H, a structure 300H is formed based on the structure 300G by forming first openings 342, 344, and 346 through the first conductive layer 312 and the first dielectric layer 210 to expose at least a portion of the pad structures of the second metallization layer 230′ (e.g., the first opening 346 exposing a portion of the pad structure 236′); and by forming second openings 352, 354, and 356 through the third conductive layer 332 and the second dielectric layer 240′ to expose at least a portion of the conductive studs 324 and 290 (e.g., the second opening 356 exposing a portion of the conductive stud 290). In some aspects, the first openings 342, 344, and 346 and the second openings 352, 354, and 356 may be formed based on mechanical drilling or laser drilling (e.g., by using a CO₂ laser). In some aspects, as the conductive studs (e.g., the conductive stud 290) increase the overall margin for the drilling the openings (e.g., the first opening 346 and the second opening 356), the risk of having the drilling processes punching through the openings 346 and 356 may be reduced without increasing the thickness of the second metallization layer 230′.

As shown in FIG. 3I, a structure 300I is formed based on the structure 300H by forming a first metallization layer 220 on the first surface 212 of the first dielectric layer 210 based on the first conductive layer 312, forming a third metallization layer 250 on the second surface 244 of the second dielectric layer 240 based on the third conductive layer 332, forming the first via structures 362, 364, and 282 based on the first openings 342, 344, and 346, and forming the second via structures 372, 374, and 284′ based on the second openings 352, 354, and 356.

In some aspects, the first metallization layer 220 may include pad structures (e.g., the pad structure 226) and trace structures (e.g., the trace structures 222 and 224). In some aspects, the first metallization layer 220 may be formed based on patterning the first conductive layer 312 to become conductive patterns, performing a plating process to increase the thickness of the conductive patterns (as well as filling the first openings 342, 344, and 346 to form the first via structures 362, 364, and 282), and optionally performing an etching and/or a cleaning process to remove excessive conductive materials on the first surface 212 of the first dielectric layer 210. In some aspects, the material and the thickness of the first metallization layer 220 may be as discussed above with reference to FIG. 2B.

In some aspects, the third metallization layer 250 may include pad structures (e.g., the pad structures 254 and 256) and trace structures (e.g., the trace structure 252). In some aspects, the third metallization layer 250 may be formed based on patterning the third conductive layer 332 to become conductive patterns, performing a plating process to increase the thickness of the conductive patterns (as well as filling the second openings 352, 354, and 356 to form the second via structures 372, 374, and 284′), and optionally performing an etching and/or a cleaning process to remove excessive conductive materials on the second surface 244′ of the second dielectric layer 240′. In some aspects, the material and the thickness of the third metallization layer 250 may be as discussed above with reference to FIG. 2B.

As shown in FIG. 3J, a structure 300J is formed based on the structure 300I by forming a first solder resist layer 260 covering at least a portion of the first surface 212 of the first dielectric layer 210 and a portion of the first metallization layer 220; and forming a second solder resist layer 270 covering at least a portion of the second surface 244′ of the second dielectric layer 240′ and a portion of the third metallization layer 250. In some aspects, the region 380 in FIG. 3J may correspond to the portion of the second substrate example 200B depicted in FIG. 2B.

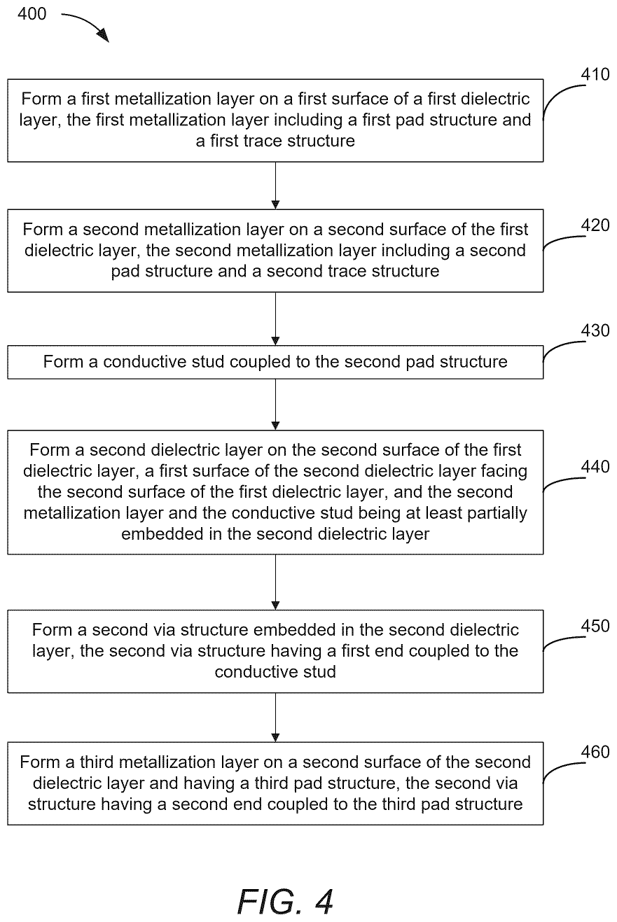

FIG. 4 illustrates a method 400 for manufacturing a substrate (such as a substrate for an IC package incorporating the features of the second substrate example 200B or the structure 300J), according to aspects of the disclosure. In some aspects, FIGS. 3A-3J may depict the substrate at different stages of manufacturing according to the method 400.

At operation 410, a first metallization layer (e.g., the first metallization layer 220) can be formed on a first surface of a first dielectric layer (e.g., the first dielectric layer 210). In some aspects, the first metallization layer may include a first pad structure (e.g., the pad structure 226) and a first trace structure (e.g., the trace structure 224). In some aspects, the first metallization layer may be formed based on a first conductive layer (e.g., the first conductive layer 312) on the first surface of the first dielectric layer.

In some aspects, the method 400 may further include attaching the first dielectric layer to a detachable copper foil structure (e.g., the structure 300A), where the detachable copper foil structure may include the first conductive layer and a carrier (e.g., the carrier 314) disposed on the first conductive layer. In some aspects, the first dielectric layer 210 may include a dielectric material with pre-impregnated reinforcement components embedded therein. In some aspects, the first conductive layer may include a conductive material such as copper.

At operation 420, a second metallization layer (e.g., the second metallization layer 230′) can be formed on a second surface of the first dielectric layer. In some aspects, the second metallization layer may include a second pad structure (e.g., the pad structure 236′) and a second trace structure (e.g., the trace structure 234′). In some aspects, the second metallization layer may be formed based on a second conductive layer (e.g., the second conductive layer 316) on the second surface of the first dielectric layer. In some aspects, the first dielectric layer may be pre-manufactured with the second conductive layer formed thereon before being attached to the detachable copper foil structure.

At operation 430, a conductive stud (e.g., the conductive stud 290) can be formed, where the conductive stud is coupled to the second pad structure. In some aspects, the conductive stud may be formed based on performing a masking process and performing a plating process, as illustrated with reference to FIGS. 3D and 3E.

At operation 440, a second dielectric layer (e.g., the second dielectric layer 240′) can be formed on the second surface of the first dielectric layer. In some aspects, a first surface (e.g., the surface 242′) of the second dielectric layer may face the second surface (e.g., the surface 214) of the first dielectric layer, and the second metallization layer and the conductive stud may be at least partially embedded in the second dielectric layer. In some aspects, operation 440 may include attaching an RCC layer to the first dielectric layer after the second metallization layer and the conductive stud are formed. In some aspects, the RCC layer includes the second dielectric layer and a third conductive layer (e.g., the third conductive layer 332) on the second dielectric layer.

In some aspects, the second dielectric layer 240′ may be free from having glass fibers embedded therein. In some aspects, the second dielectric layer 240′ may be formed based on ABF, PID, and/or RCC.

At operation 450, a second via structure (e.g., the via structure 284′) can be formed. In some aspects, the second via structure may be embedded in the second dielectric layer. In some aspects, the second via structure may have a first end coupled to the conductive stud. In some aspects, the second via structure may be formed based on forming a second opening (e.g., the opening 356) through the second conductive layer and the second dielectric layer to expose at least a portion of the conductive stud, and forming the second via structure based on the second opening.

In some aspects, operation 450 may further include forming a first via structure (e.g., the via structure 282) that is embedded in the first dielectric layer and having a first end coupled to the first pad structure. In some aspects, the first via structure may have a first end coupled to the first pad structure. In some aspects, the first via structure may be formed based on removing the carrier to expose the first conductive layer after the conductive stud is formed, forming a first opening (e.g., the opening 346) through the first conductive layer and the first dielectric layer to expose at least a portion of the second pad structure, and forming the first via structure based on the first opening. In some aspects, as shown in FIG. 3I, the first metallization layer and the first via structure may be formed based on a same plating process.

At operation 460, a third metallization layer (e.g., the third metallization layer 250) on a second surface of the second dielectric layer and having a third pad structure (e.g., the pad structure 254). In some aspects, the second via structure may have a second end coupled to the third pad structure. In some aspects, as shown in FIG. 3I, the third metallization layer and the second via structure may be formed based on a same plating process.

After operation 460, in some aspects as shown in FIG. 3J, a first solder resist layer (e.g., the first solder resist layer 260) can be formed covering at least a portion of the first surface of the first dielectric layer and a portion of the first metallization layer. After operation 460, in some aspects as shown in FIG. 3J, a second solder resist layer (e.g., the second solder resist layer 270) can be formed covering at least a portion of the second surface of the second dielectric layer and a portion of the third metallization layer.

In some aspects, a width of the conductive stud may be less than a width of the second pad structure. In some aspects, a thickness of the second trace structure or a thickness of the second pad structure may be equal to or less than 6 μm. In some aspects, a thickness of the conductive stud may be equal to or greater than 5 μm.

A technical advantage of the method 400 corresponds to manufacturing a substrate that includes a metallization layer having a reduced thickness and a conductive stud coupled to a pad structure of the metallization layer to increase the overall margin for the drilling the openings for forming stacked via structures. Accordingly, the risk of having the drilling processes punching through the openings for the stacked via structures may be reduced without increasing the thickness of the metallization layer. The overall thickness of the IC package incorporating such substrate may be reduced. Also, the reliably stacked via structures according to the method 400 may reduce the size of the via structures and/or provide better routing capabilities.

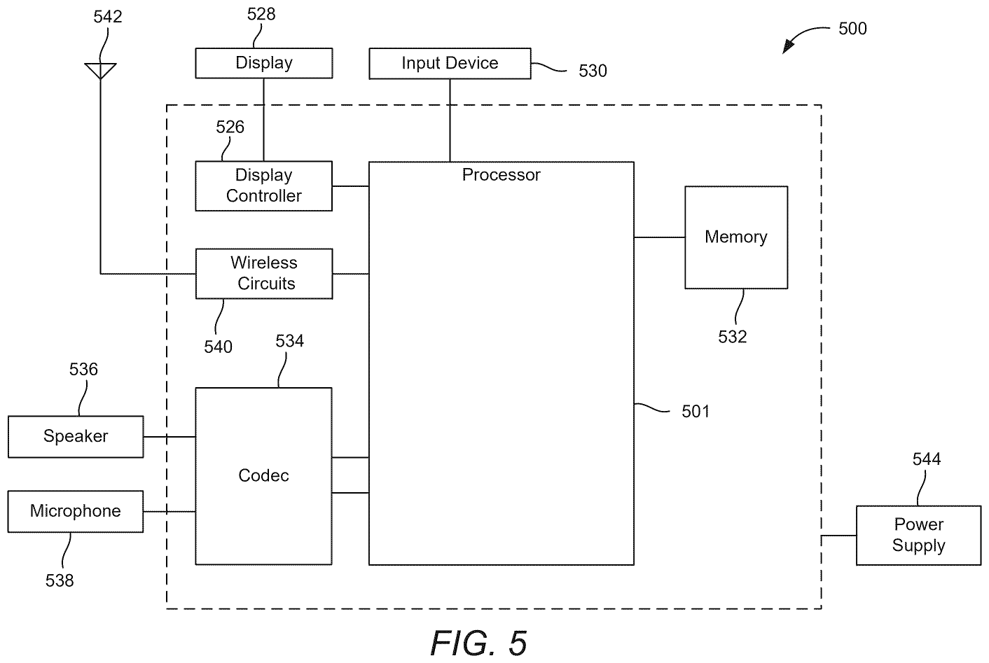

FIG. 5 illustrates a mobile device 500, according to aspects of the disclosure. In some aspects, the mobile device 500 may be implemented by including one or more IC devices including the package substrates as disclosed herein.

In some aspects, mobile device 500 may be configured as a wireless communication device. As shown, mobile device 500 includes processor 501. Processor 501 may be communicatively coupled to memory 532 over a link, which may be a die-to-die or chip-to-chip link. Mobile device 500 also includes display 528 and display controller 526, with display controller 526 coupled to processor 501 and to display 528. The mobile device 500 may include input device 530 (e.g., physical, or virtual keyboard), power supply 544 (e.g., battery), speaker 536, microphone 538, and wireless antenna 542. In some aspects, the power supply 544 may directly or indirectly provide the supply voltage for operating some or all of the components of the mobile device 500.

In some aspects, FIG. 5 may include coder/decoder (CODEC) 534 (e.g., an audio and/or voice CODEC) coupled to processor 501; speaker 536 and microphone 538 coupled to CODEC 534; and wireless circuits 540 (which may include a modem, RF circuitry, filters, etc.) coupled to wireless antenna 542 and to processor 501.

In some aspects, one or more of processor 501 (e.g., SoCs, application processor (AP)), display controller 526, memory 532, CODEC 534, and wireless circuits 540 (e.g., baseband interface) including IC devices that are packaged as IC packages and including package substrates according to the various aspects described in this disclosure.

It should be noted that although FIG. 5 depicts a mobile device 500, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

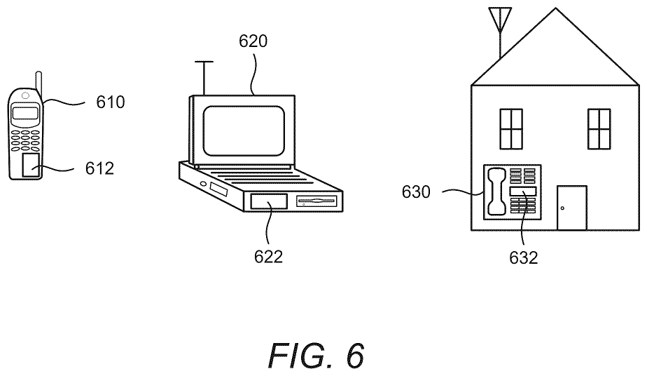

FIG. 6 illustrates various electronic devices 610, 620, and 630 that may incorporate IC devices 612, 622, and 632, which may be packaged as IC packages having package substrates described herein, according to aspects of the disclosure.

For example, a mobile phone device 610, a laptop computer device 620, and a fixed location terminal device 630 may each be considered generally user equipment (UE) and may include one or more IC devices, such as IC devices 612, 622, and 632, and a power supply to provide the supply voltages to power the IC devices. The IC devices 612, 622, and 632 may be, for example, correspond to an IC device packaged as an IC package having a package substrate manufactured based on the examples described above with reference to FIGS. 2B and 3A-3J.

The devices 610, 620, and 630 illustrated in FIG. 6 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-6 may be rearranged and/or combined into a single component, process, feature, or function or incorporated in several components, processes, or functions. Additional elements, components, processes, and/or functions may also be added without departing from the disclosure. In some implementations, FIGS. 1-6 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A substrate for an integrated circuit (IC) package, comprising: a first dielectric layer; a first metallization layer on a first surface of the first dielectric layer, the first metallization layer including a first pad structure and a first trace structure; a second metallization layer on a second surface of the first dielectric layer, the second metallization layer including a second pad structure and a second trace structure; a conductive stud coupled to the second pad structure; a second dielectric layer on the second surface of the first dielectric layer, a first surface of the second dielectric layer facing the second surface of the first dielectric layer, and the second metallization layer and the conductive stud being at least partially embedded in the second dielectric layer; a second via structure embedded in the second dielectric layer, the second via structure having a first end coupled to the conductive stud; and a third metallization layer on a second surface of the second dielectric layer and having a third pad structure, the second via structure having a second end coupled to the third pad structure.

Clause 2. The substrate of clause 1, further comprising: a first solder resist layer covering at least a portion of the first surface of the first dielectric layer and a portion of the first metallization layer; and a second solder resist layer covering at least a portion of the second surface of the second dielectric layer and a portion of the third metallization layer.

Clause 3. The substrate of any of clauses 1 to 2, further comprising: a first via structure embedded in the first dielectric layer, the first via structure having a first end coupled to the second pad structure and a second end coupled to the first pad structure of the first metallization layer.

Clause 4. The substrate of any of clauses 1 to 3, wherein a width of the conductive stud is less than a width of the second pad structure.

Clause 5. The substrate of any of clauses 1 to 4, wherein a thickness of the second trace structure is less than a combined thickness of the second pad structure and the conductive stud.

Clause 6. The substrate of any of clauses 1 to 5, wherein: a thickness of the second trace structure or a thickness of the second pad structure is equal to or less than 6 micrometers (μm).

Clause 7. The substrate of clause 6, wherein: the thickness of the second trace structure or the thickness of the second pad structure ranges from 2 μm to 5 μm.

Clause 8. The substrate of any of clauses 1 to 7, wherein: a thickness of the conductive stud is equal to or greater than 5 micrometers (μm).

Clause 9. The substrate of clause 8, wherein: the thickness of the conductive stud ranges from 5 μm to 30 μm.

Clause 10. The substrate of any of clauses 1 to 9, wherein: the second dielectric layer is free from having glass fibers embedded therein.

Clause 11. A method of manufacturing a substrate for an integrated circuit (IC) package, comprising: forming a first metallization layer on a first surface of a first dielectric layer, the first metallization layer including a first pad structure and a first trace structure; forming a second metallization layer on a second surface of the first dielectric layer, the second metallization layer including a second pad structure and a second trace structure; forming a conductive stud coupled to the second pad structure; forming a second dielectric layer on the second surface of the first dielectric layer, a first surface of the second dielectric layer facing the second surface of the first dielectric layer, and the second metallization layer and the conductive stud being at least partially embedded in the second dielectric layer; forming a second via structure embedded in the second dielectric layer, the second via structure having a first end coupled to the conductive stud; and forming a third metallization layer on a second surface of the second dielectric layer and having a third pad structure, the second via structure having a second end coupled to the third pad structure.

Clause 12. The method of clause 11, wherein the forming the conductive stud comprises performing a masking process and performing a plating process.

Clause 13. The method of any of clauses 11 to 12, wherein the forming the second dielectric layer comprises attaching a resin coated copper layer to the first dielectric layer after the second metallization layer and the conductive stud are formed.

Clause 14. The method of any of clauses 11 to 13, further comprising: attaching the first dielectric layer to a detachable copper foil structure, the detachable copper foil structure including a first conductive layer on the first surface of the first dielectric layer and a carrier disposed on the first conductive layer; and forming a second conductive layer on the second surface of the first dielectric layer, wherein the first metallization layer is formed based on the first conductive layer, and the second metallization layer is formed based on the second conductive layer.

Clause 15. The method of clause 14, further comprising: removing the carrier to expose the first conductive layer after the conductive stud is formed; forming a first opening through the first conductive layer and the first dielectric layer to expose at least a portion of the second pad structure; and forming a first via structure based on the first opening, the first via structure being embedded in the first dielectric layer and having a first end coupled to the first pad structure.

Clause 16. The method of any of clauses 14 to 15, wherein the forming the second via structure comprises: forming a second opening through the second conductive layer and the second dielectric layer to expose at least a portion of the conductive stud; and forming the second via structure based on the second opening.

Clause 17. The method of any of clauses 11 to 16, further comprising: forming a first solder resist layer covering at least a portion of the first surface of the first dielectric layer and a portion of the first metallization layer; and forming a second solder resist layer covering at least a portion of the second surface of the second dielectric layer and a portion of the third metallization layer.

Clause 18. The method of any of clauses 11 to 17, wherein a width of the conductive stud is less than a width of the second pad structure.

Clause 19. The method of any of clauses 11 to 18, wherein: a thickness of the second trace structure or a thickness of the second pad structure is equal to or less than 6 micrometers (μm).

Clause 20. The method of any of clauses 11 to 19, wherein: a thickness of the conductive stud is equal to or greater than 5 micrometers (μm).

Clause 21. The method of any of clauses 11 to 20, wherein: the second dielectric layer is free from having glass fibers embedded therein.

Clause 22. An electronic device, comprising: an integrated circuit (IC) package including: a first dielectric layer; a first metallization layer on a first surface of the first dielectric layer, the first metallization layer including a first pad structure and a first trace structure; a second metallization layer on a second surface of the first dielectric layer, the second metallization layer including a second pad structure and a second trace structure; a conductive stud coupled to the second pad structure; a second dielectric layer on the second surface of the first dielectric layer, a first surface of the second dielectric layer facing the second surface of the first dielectric layer, and the second metallization layer and the conductive stud being at least partially embedded in the second dielectric layer; a second via structure embedded in the second dielectric layer, the second via structure having a first end coupled to the conductive stud; and a third metallization layer on a second surface of the second dielectric layer and having a third pad structure, the second via structure having a second end coupled to the third pad structure.

Clause 23. The electronic device of clause 22, wherein the IC package further comprises: a first IC disposed over and electrically coupled to the first metallization layer; and a second IC disposed under and electrically coupled to the third metallization layer.

Clause 24. The electronic device of any of clauses 22 to 23, wherein the IC package further comprises: a first solder resist layer covering at least a portion of the first surface of the first dielectric layer and a portion of the first metallization layer; and a second solder resist layer covering at least a portion of the second surface of the second dielectric layer and a portion of the third metallization layer.

Clause 25. The electronic device of any of clauses 22 to 24, wherein a width of the conductive stud is less than a width of the second pad structure.

Clause 26. The electronic device of any of clauses 22 to 25, wherein a thickness of the second trace structure is less than a combined thickness of the second pad structure and the conductive stud.

Clause 27. The electronic device of any of clauses 22 to 26, wherein: a thickness of the second trace structure or a thickness of the second pad structure is equal to or less than 6 micrometers (μm).

Clause 28. The electronic device of any of clauses 22 to 27, wherein: a thickness of the conductive stud is equal to or greater than 5 micrometers (μm).

Clause 29. The electronic device of any of clauses 22 to 28, wherein: the second dielectric layer is free from having glass fibers embedded therein.

Clause 30. The electronic device of any of clauses 22 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. A substrate for an integrated circuit (IC) package, comprising:
a first dielectric layer;
a first metallization layer on a first surface of the first dielectric layer, the first metallization layer including a first pad structure and a first trace structure;
a second metallization layer on a second surface of the first dielectric layer, the second metallization layer including a second pad structure and a second trace structure;
a conductive stud coupled to the second pad structure;
a second dielectric layer on the second surface of the first dielectric layer, a first surface of the second dielectric layer facing the second surface of the first dielectric layer, and the second metallization layer and the conductive stud being at least partially embedded in the second dielectric layer;
a second via structure embedded in the second dielectric layer, the second via structure having a first end coupled to the conductive stud; and
a third metallization layer on a second surface of the second dielectric layer and having a third pad structure, the second via structure having a second end coupled to the third pad structure.

2. The substrate of claim 1, further comprising:
a first solder resist layer covering at least a portion of the first surface of the first dielectric layer and a portion of the first metallization layer; and
a second solder resist layer covering at least a portion of the second surface of the second dielectric layer and a portion of the third metallization layer.

3. The substrate of claim 1, further comprising:
a first via structure embedded in the first dielectric layer, the first via structure having a first end coupled to the second pad structure and a second end coupled to the first pad structure of the first metallization layer.

4. The substrate of claim 1, wherein a width of the conductive stud is less than a width of the second pad structure.

5. The substrate of claim 1, wherein a thickness of the second trace structure is less than a combined thickness of the second pad structure and the conductive stud.

6. The substrate of claim 1, wherein:
a thickness of the second trace structure or a thickness of the second pad structure is equal to or less than 6 micrometers (μm).

7. The substrate of claim 6, wherein:
the thickness of the second trace structure or the thickness of the second pad structure ranges from 2 μm to 5 μm.

8. The substrate of claim 1, wherein:
a thickness of the conductive stud is equal to or greater than 5 micrometers (μm).

9. The substrate of claim 8, wherein:
the thickness of the conductive stud ranges from 5 μm to 30 μm.

10. The substrate of claim 1, wherein:
the second dielectric layer is free from having glass fibers embedded therein.

11. A method of manufacturing a substrate for an integrated circuit (IC) package, comprising:
forming a first metallization layer on a first surface of a first dielectric layer, the first metallization layer including a first pad structure and a first trace structure;
forming a second metallization layer on a second surface of the first dielectric layer, the second metallization layer including a second pad structure and a second trace structure;
forming a conductive stud coupled to the second pad structure;
forming a second dielectric layer on the second surface of the first dielectric layer, a first surface of the second dielectric layer facing the second surface of the first dielectric layer, and the second metallization layer and the conductive stud being at least partially embedded in the second dielectric layer;
forming a second via structure embedded in the second dielectric layer, the second via structure having a first end coupled to the conductive stud; and
forming a third metallization layer on a second surface of the second dielectric layer and having a third pad structure, the second via structure having a second end coupled to the third pad structure.

12. The method of claim 11, wherein the forming the conductive stud comprises performing a masking process and performing a plating process.

13. The method of claim 11, wherein the forming the second dielectric layer comprises attaching a resin coated copper layer to the first dielectric layer after the second metallization layer and the conductive stud are formed.

14. The method of claim 11, further comprising:
attaching the first dielectric layer to a detachable copper foil structure, the detachable copper foil structure including a first conductive layer on the first surface of the first dielectric layer and a carrier disposed on the first conductive layer; and
forming a second conductive layer on the second surface of the first dielectric layer,
wherein the first metallization layer is formed based on the first conductive layer, and the second metallization layer is formed based on the second conductive layer.

15. The method of claim 14, further comprising:
removing the carrier to expose the first conductive layer after the conductive stud is formed;
forming a first opening through the first conductive layer and the first dielectric layer to expose at least a portion of the second pad structure; and
forming a first via structure based on the first opening, the first via structure being embedded in the first dielectric layer and having a first end coupled to the first pad structure.

16. The method of claim 14, wherein the forming the second via structure comprises:
forming a second opening through the second conductive layer and the second dielectric layer to expose at least a portion of the conductive stud; and
forming the second via structure based on the second opening.

17. The method of claim 11, further comprising:
forming a first solder resist layer covering at least a portion of the first surface of the first dielectric layer and a portion of the first metallization layer; and
forming a second solder resist layer covering at least a portion of the second surface of the second dielectric layer and a portion of the third metallization layer.

18. The method of claim 11, wherein a width of the conductive stud is less than a width of the second pad structure.

19. The method of claim 11, wherein:
a thickness of the second trace structure or a thickness of the second pad structure is equal to or less than 6 micrometers (μm).

20. The method of claim 11, wherein:
a thickness of the conductive stud is equal to or greater than 5 micrometers (μm).

21. The method of claim 11, wherein:
the second dielectric layer is free from having glass fibers embedded therein.

22. An electronic device, comprising:
an integrated circuit (IC) package including:
a first dielectric layer;
a first metallization layer on a first surface of the first dielectric layer, the first metallization layer including a first pad structure and a first trace structure;
a second metallization layer on a second surface of the first dielectric layer, the second metallization layer including a second pad structure and a second trace structure;
a conductive stud coupled to the second pad structure;
a second dielectric layer on the second surface of the first dielectric layer, a first surface of the second dielectric layer facing the second surface of the first dielectric layer, and the second metallization layer and the conductive stud being at least partially embedded in the second dielectric layer;
a second via structure embedded in the second dielectric layer, the second via structure having a first end coupled to the conductive stud; and
a third metallization layer on a second surface of the second dielectric layer and having a third pad structure, the second via structure having a second end coupled to the third pad structure.

23. The electronic device of claim 22, wherein the IC package further comprises:
a first IC disposed over and electrically coupled to the first metallization layer; and
a second IC disposed under and electrically coupled to the third metallization layer.

24. The electronic device of claim 22, wherein the IC package further comprises:
a first solder resist layer covering at least a portion of the first surface of the first dielectric layer and a portion of the first metallization layer; and
a second solder resist layer covering at least a portion of the second surface of the second dielectric layer and a portion of the third metallization layer.

25. The electronic device of claim 22, wherein a width of the conductive stud is less than a width of the second pad structure.

26. The electronic device of claim 22, wherein a thickness of the second trace structure is less than a combined thickness of the second pad structure and the conductive stud.

27. The electronic device of claim 22, wherein:
a thickness of the second trace structure or a thickness of the second pad structure is equal to or less than 6 micrometers (μm).

28. The electronic device of claim 22, wherein:
a thickness of the conductive stud is equal to or greater than 5 micrometers (μm).

29. The electronic device of claim 22, wherein:
the second dielectric layer is free from having glass fibers embedded therein.

30. The electronic device of claim 22, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
